(19) United States
(12) Patent Application Publication
(10) Pub. No.: US 2009/0315159 A1
(43) Pub. Date: Dec. 24, 2009

(54) LEADFRAMES HAVING BOTH ENHANCED-ADHESION AND SMOOTH SURFACES AND METHODS TO FORM THE SAME

(76) Inventor: Donald Charles Abbott, Norton, MA (US)

Correspondence Address: TEXAS INSTRUMENTS INCORPORATED, P O BOX 655474, M/S 3999, DALLAS, TX, 75265, US

(21) Appl. No.: 12/143,415

(22) Filed: Jun. 20, 2008

(51) Int. Cl. H01L 23/495; H01L 21/00; B21D 53/00

(52) U.S. Cl. 257/666; 438/123; 29/34 R; 257/E23.031

(57) ABSTRACT

Example leadframes having both rough surfaces to enhance adhesion to molding compounds and selectively smoothed surfaces to enhance bonding wire performance, and methods to form the same are disclosed. A disclosed example packaged integrated circuit chip includes a bond wire, a leadframe having a die pad coupled to a carrier rail, and an inner lead coupled to an outer lead via a dam bar, the inner lead having a first portion having a rough surface and a second portion having a smoothed surface, a first end of the bond wire attached to the second portion of the inner lead, an integrated circuit attached to the die pad, a second end of the bond wire attached to a pad disposed on the integrated circuit, and a molding compound to encapsulate the inner lead, the integrated circuit and the bond wire.

### FIELD OF THE DISCLOSURE

This disclosure relates generally to semiconductor packaging and, more particularly, to leadframes having both rough surfaces to enhance adhesion to molding compounds and selectively smoothed surfaces to enhance bonding wire performance, and methods to form the same are disclosed.

### BACKGROUND

In semiconductor packaging, an integrated circuit is attached to a leadframe and then encapsulated in a molding compound to protect the integrated circuit. An example leadframe is formed by stamping a pattern in a layer of conductive material (e.g., a metal). The stamping of the example leadframe results in leads that have a non-planar or rounded top surface, which may result in decrease wire bonding performance. To improve wire bonding performance, at least the inner or distal ends of the leads of the example leadframe are subsequently coined. An example coining operation makes the leads substantially planar or flat, and reduces the thickness of the stamped leads by 30% to 50%, which may introduce mechanical stress into the leads.

Some example leadframes are roughened, formed or constructed to have a granular surface that improves the adhesion between the leadframe and the molding compound, and which improves the moisture sensitivity level performance of a resultant packaged integrated circuit. The granular surface of a leadframe may be formed using, for example, plating or etching. The roughening of the leadframe surface is performed after the stamping and coining operations because it is not desirable, in practice, to stamp a roughened surface. For example, coining of a plated surface would reduce the thickness of the plating and introduce mechanical stress into the plating. Moreover, were roughening performed prior to stamping, edges that are formed by the stamping process will not be or remain rough, and substantially all of the original base metal layer (including those portions that will be removed during stamping) would need to be roughened rather than just the leadframe itself.

In some examples, the roughened surface is limited to a desired portion of the leadframe (e.g., the portion of the leadframe within the dam bar). However, restricting the rough surface to only portions of the inner leads of the leadframe is impractical. In particular, such rough surface formation operations would require masks having fine-dimensional features that are generally beyond the capabilities of existing leadframe manufacturing tools, and coining causes the inner ends of the leads to be in a different plane than the rest of the leadframe, which further complicates or limits the precise formation of the granular surface via masks.

The granular surface of some leadframes cause, among other things, decreased wire bonding performance. Specifically, granular surfaces may appear dull to a computer vision system used to automatically place bonding wires. As a result, the computer vision system may place bonding wires inaccurately, which may result in electrical failure(s) of a packaged integrated circuit. Moreover, such granular surfaces may damage a capillary of a bonding wire tool, which holds the threaded bonding wire. In some examples, the capillary may also pick up micro-contaminants from a granular surface. Such micro-contaminants and the damage experienced by the capillary can reduce the operative or working life of the capillary and, at the same time, affect the consistency of the wire bonding characteristics (e.g., bond strength, etc.). Further still, while a granular surface may improve the adhesion of an integrated circuit to a die pad, it may also lead to, for example, resin bleed out. In some circumstances, resin bleed out can degrade the moisture sensitivity level performance of a final packaged semiconductor.

### SUMMARY

Example leadframes having both rough surfaces to enhance adhesion to molding compounds and selectively smoothed surfaces to enhance bonding wire performance, and methods to form the same are disclosed. In disclosed examples, after a granular surface is formed on a stamped and coined leadframe, leads of the leadframe are further processed to have a portion that is at least one of smoothed, smoother, less rough or less granular than the granular surface. Example smoothed portions of the leads are located at the inner or distal ends of the inner leads of the leadframe adjacent to the die pad, where bonding wires are to be placed. To avoid the potential for rough surface defects near the transition area(s) from coined to uncoined portions and to reduce the potential for chipping of a planishing punch used to smooth the desired areas, only a portion of the coined areas of the leads are smoothed by the example planishing and/or light spanking operations described herein. The smoothed portions of the leads substantially reduce the damage experienced by the capillary of the bonding wire tool and, at the same time, the smoothed portions improve the consistency of the wire bonding operations (e.g., bond strength, bond wire shape, etc.). Moreover, the smoothed portions of the leads improve the accuracy of the computer vision system used to place bonding wires. Further, because only those portions of the leads where bond wires are to be placed are smoothed, the adhesion strength of the molding compound to the rest of the leadframe remains substantially unchanged. Further still, the example planishing operations described herein reduce the thickness of the smoothed areas by less than 5% to avoid reducing the thickness of the plating and to avoid introducing mechanical stress into to the smoothed areas. While the example planishing operations form the smoothed areas they are insufficient to flatten the rounding of the top surfaces of the leads caused by stamping of the leads and, thus, are mechanically different from the coining that is performed after stamping and before roughening.

In disclosed examples, an outer annular portion of the die pad is smoothed. The smoothed outer portion of the die pad reduces resin bleed out, thus, improving the moisture sensitivity level of the final packaged semiconductor. In examples described herein, the inner portion of the die pad is left rough (i.e., granular) to maintain the adhesion strength of the integrated circuit to the die pad.

The example methods and apparatus described herein may be implemented or carried out in conjunction with any past, present or future leadframe manufacturing equipment without the need for an extra process. For example, the methods described herein may be implemented during a cut and offset process. Additionally or alternatively, the disclosed methods and apparatus can be implemented or carried out in conjunction with any past, present or future leadframe roughening processes, without the need for masking during leadframe roughening processes or plating processes. Moreover, the disclosed examples result in highly selective and precisely located smoothed areas. In some examples, the smoothed portions of the leads or die pad are formed by carrying out a planishing operation, a spanking operation, a light compressing operation or any combination thereof on the granular surface.

The following terms are used herein and are defined here for ease of reference:

stamping—a mechanical process used herein to pattern a sheet or layer of material;

coining—a mechanical process used herein to render a surface substantially planar or flat;

planishing, spanking—mechanical processes used herein to smooth a surface or a material;

plating—a chemical process used herein to apply or coat a first layer of material with a second layer of material; and

etching—a chemical process used herein to remove parts of or roughen a surface by application of one or more chemicals.

A disclosed example leadframe for a semiconductor package includes a die pad to receive an integrated circuit and coupled to a carrier rail, and an inner lead to receive a bond wire and coupled to an outer lead via a dam bar, the inner lead having a first portion having a rough surface and a second portion having a reduced roughness surface relative to the first portion.

A disclosed example packaged integrated circuit includes a bond wire, a leadframe having a die pad coupled to a tie strap, and an inner lead coupled to an outer lead via a dam bar, the inner lead having a first portion having a rough surface and a second portion having a smoothed surface, a first end of the bond wire attached to the second portion of the inner lead, an integrated circuit attached to the die pad, a second end of the bond wire attached to a pad disposed on the integrated circuit, and a molding compound to encapsulate the inner lead, the integrated circuit and the bond wire.

A disclosed example method includes processing a first conductive material to form a leadframe, the leadframe having a die pad and an inner lead, forming a layer of a second conductive material on the leadframe, the layer having a granular surface, and selectively planishing the layer to smooth a surface of the leadframe to have a selectively less granular surface.

A disclosed example apparatus includes a stamping tool to form a leadframe in a first conductive material, the leadframe having a die pad and a lead, a plating tool to form a layer of a second conductive material on the leadframe, the layer having a granular surface, and a cut and offset tool to selectively planish the layer to smooth a surface of the leadframe.

### BRIEF DESCRIPTION OF THE DRAWINGS

FIG. 1 is an illustration of an example enhanced-adhesion leadframe having selectively smooth surfaces.

FIG. 2 illustrates an example leadframe manufacturing line that may be used to manufacture the example leadframe of FIG. 1.

FIG. 3 is a flow chart of an example process that may be carried out to form the example leadframe of FIG. 1.

Wherever possible, the same reference numbers will be used throughout the drawing(s) and accompanying written description to refer to the same or like parts. As used in this patent, stating that any part (e.g., a layer, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

Example leadframes having both rough surfaces to enhance adhesion to molding compounds and selectively smoothed surfaces to enhance bonding wire performance, and methods to form the same are disclosed. Although the example methods and apparatus described herein generally relate to leadframes, the disclosure is not limited to such. On the contrary, the teachings of this disclosure may be applied to any semiconductor manufacturing process. Moreover, while example methods and apparatus are described herein with reference to a quad flat packaged (QFP) semiconductor device, the disclosed methods and apparatus may be readily used to form a leadframe for any other type(s) of semiconductor packages such as, for example, a dual inline package (DIP), a small outline integrated circuit (SOIC) package, a quad flat no-lead (QFN) package, etc.

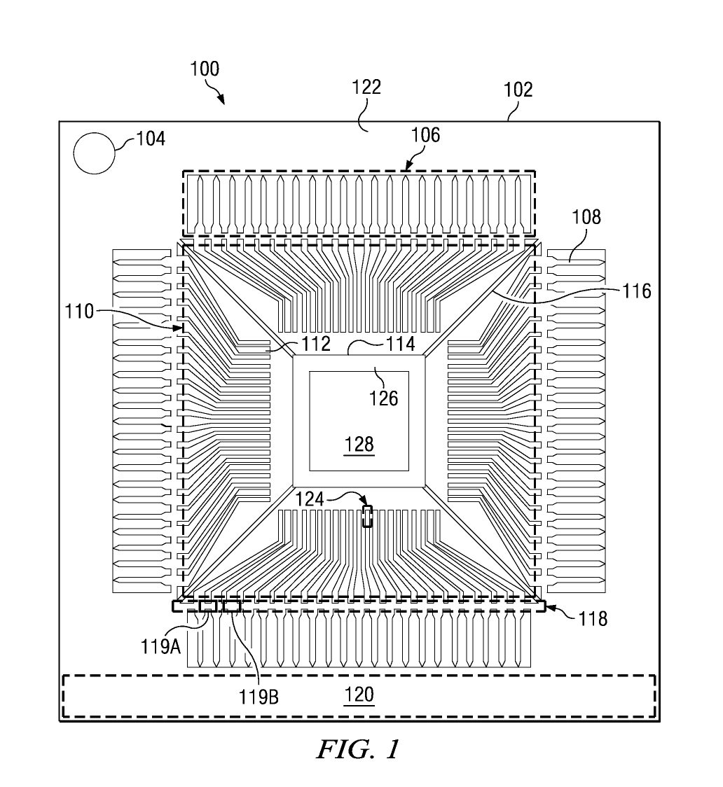

FIG. 1 illustrates an example leadframe 100 having one or more selectively smoothed surfaces 124, 126 constructed in accordance with the teachings of this disclosure. The example leadframe 100 of FIG. 1 may be formed via, for example, a stamping process and a plating process. The example leadframe 100 is formed from an electrically conductive material such as, for example, copper, a copper alloy, alloy 42 (i.e., an alloy of 42% nickel and 58% iron), Kovar™ or any other metal or metal alloy. The example leadframe 100 includes one or more features such as an index hole 104 to facilitate alignment or placement or both during a semiconductor packaging processes.

To facilitate electrical connections between an integrated circuit (not shown) and a circuit board to which a packaged integrated circuit chip constructed using the leadframe 100 is attached, the example leadframe 100 of FIG. 1 includes external lead sections (one of which is designated at reference numeral 106) and an internal lead section 110. The example external lead sections 106 of FIG. 1 include one or more external leads (one of which is designated at reference numeral 108). The example external leads 108 of FIG. 1 are used to facilitate electrical or mechanical attachment of a packaged chip constructed using the leadframe 100 to, for example, a circuit board. The example internal lead section 110 of FIG. 1 includes one or more internal leads (one of which is designated at reference numeral 112) for respective ones of the external leads 108. The example internal leads 112 of FIG. 1 facilitate electrical connections between the external leads 108 and the integrated circuit.

To allow an integrated circuit (not shown) to be attached to the leadframe 100, the example leadframe 100 of FIG. 1 includes a die pad 114 that is mechanically connected to the leadframe 100 via one or more tie straps (one of which is designated at reference numeral 116). An integrated circuit may be attached to the die pad 114 using, for example, an epoxy adhesive. As shown in FIG. 1, neither the example tie straps 116 nor the example die pad 114 physically contact any of the internal leads 112 or any of the external leads 108. The example tie straps 116 of FIG. 1 are formed integral with carrier rails (one of which is designated at reference numeral 120). In the illustrated example of FIG. 1, dam bars (one of which is designated at reference numeral 118) are disposed between the internal lead section 110 and the external lead sections 106. The example dam bars 118 of FIG. 1 are formed integral with the internal leads 112 and the external leads 108, thereby electrically coupling the internal leads 112 to respective external leads 108. During a later semiconductor packaging process (e.g., trim and form), portions of the dam bars 118 located between the external leads 108 (e.g., one of which is designated at reference numeral 119A) are removed. Removing the portions 119A of the dam bars 118 electrically isolate the external leads 108 from each other. Non-removed portions of the dam bars 118 (one of which is designated at reference numeral 119B) continue to electrically connect the internal leads 112 with respective external leads 108. The example external lead sections 106 are further connected to the carrier rails 120 that encircle the leadframe 100. The example carrier rails 120 of FIG. 1 are removed during later packaging processes (e.g., trim and form) to electrically isolate the external leads 108 from each other. The example carrier rails 120 are disposed on the edges of the example leadframe 100 to allow a plurality of leadframes to be placed on a sheet of conductive material to, for example, facilitate manufacturing.

The example leadframe 100 of FIG. 1 is formed to have a granular surface 122 (e.g., a surfacing having an average roughness of approximately 1 to 2 micrometers (μm)) to facilitate mechanical adhesion of the leadframe 100 to a molding compound used to encapsulate the leadframe 100 and an integrated circuit attached to the die pad 114. The example granular surface 122 of FIG. 1 may be created by any number or type(s) of processes such as, for example, an etching process or a coating process or a plating process or any combination thereof that is applied to substantially all of both sides of the entire leadframe 100. In some examples, the granular surface 122 is only formed on the example inner lead section 110, the example tie straps 116 and the example die pad 114. While an additional or alternative mask could be used to limit formation of the granular surface 122 on only particular portions of the inner leads 112 or the die pad 114, such fine-dimensional masks are generally beyond the capabilities of existing leadframe manufacturing tools. Moreover, the inner or distal ends 124 of the inner leads 112 are generally coined after leadframe stamping to improve bonding wire placement performance. However, such coining may, in some examples, cause distal or inner ends 124 of the inner leads 112 to be in a different plane than the rest of the leadframe 100, which further complicates or limits the precise formation of the granular surface 122.

However, the example granular surface 122 of FIG. 1 causes, among other things, decreased wire bonding performance. Specifically, the example granular surface 122 of the example leadframe 100 may appear dull to a computer vision system used to automatically place bonding wires between the internal leads 112 and corresponding contacts of an integrated circuit attached to the die pad 114. As a result, the computer vision system may place bonding wires inaccurately, which may result in electrical failure(s) of a packaged integrated circuit chip. Moreover, the granular surface 122 of the leadframe 100 may damage a capillary of a bonding wire tool, which holds the threaded bonding wire. In some examples, the capillary may also pick up micro-contaminants from the granular surface 122. Such micro-contaminants and the damage experienced by the capillary can reduce the operative or working life of the capillary and, at the same time, affect the consistency of the wire bonding characteristics (e.g., bond strength, etc.).

To overcome at least these deficiencies, after the granular surface 122 is formed by etching or plating, each of the example internal leads 112 of FIG. 1 is further processed to have an inward, center-most or distal portion (one of which is designated at reference numeral 124) that is at least one of smoothed, smoother, less rough or less granular than the granular surface 122. The example portions 124 of FIG. 1 are located at the ends of the inner leads 112 adjacent to the die pad 114. The example smoothed portions 124 are formed by carrying out a planishing operation, a spanking operation, a light compressing operation or any combination thereof on the granular surface 122. An example planishing operation reduces the thickness of the portions 124 relative to other portions of the leads 112 by preferably less than 5% to reduce mechanical stress experienced by the leads 112 or to avoid changing the lateral geometries of the leads 112. The example planishing operations reduces the roughness of the surface to preferably an average roughness of 75-200 nm rms (root-mean-square) or a z-range of 0.7 to 1.1 microns. To avoid striking or affecting uncoined areas of the inner leads 112, the example planishing operation is performed with a planishing punch that strikes approximately 80% of the inward, center-most or distal portions 124. The example smoothed portions 124 of the internal leads 112 of FIG. 1 substantially reduce the damage experienced by the capillary of the bonding wire tool when placing bonding wires between the internal leads 112 and the contacts of an attached integrated circuit. At the same time, the smoothed portions 124 improve the consistency of the wire bonding operations (e.g., bond strength, bond wire shape, etc.). Moreover, the computer vision device that moves and places the bonding wire is able to more accurately detect the internal leads 112, thereby reducing the number of incorrect bonds and increasing the efficiency of the semiconductor manufacturing process.

The example granular surface 122 of FIG. 1 increases the adhesion strength between the die pad 114 and an integrated circuit attached thereto. Specifically, in a die attach process, an adhesive compound is applied to the die pad 114 and an integrated circuit is placed on the adhesive compound. The adhesive compound is typically cured by heating the adhesive compound, thereby attaching the integrated circuit to the die pad 114. The adhesive compound generally comprises an organic solvent, an organic binding compound and an inorganic filler. However, during the die attach process, the organic solvent may spread beyond the desired die attach area. Microgrooves of the granular surface 122 can facilitate this spreading of the organic binding leading to, for example, resin bleed out.

To overcome at least this deficiency, after the granular surface 122 is formed by etching or plating, the example die pad 114 of FIG. 1 may, additionally or alternatively, be further processed to have a portion 126 that is at least one of smoothed, smoother, less rough or less granular than the granular surface 122. The example smoothed portion 126 of FIG. 1 is an annular portion occurring at the outside edges of the die pad 114. The example smoothed portion 126 may be formed via planishing, a spanking operation, a light compressing operation or any combination thereof as described above in connection with the example smoothed portions 124. The interior portion 128 of the die pad 114 has the granular surface 122 to enhance the adhesion of the integrated circuit to the die pad 114, while the smoothed portion 124 reduces resin bleed out around the edges of the integrated circuit. Specifically, the outer non-granular surface 126 reduces the number of microgrooves presented to the organic solvent, thereby reducing the amount of resin bleed out. As a result of reduced resin bleed out, the overall adhesion strength between an attached integrated circuit and the leadframe 100 is increased, and the moisture sensitivity level performance of the final packaged integrated circuit chip is improved.

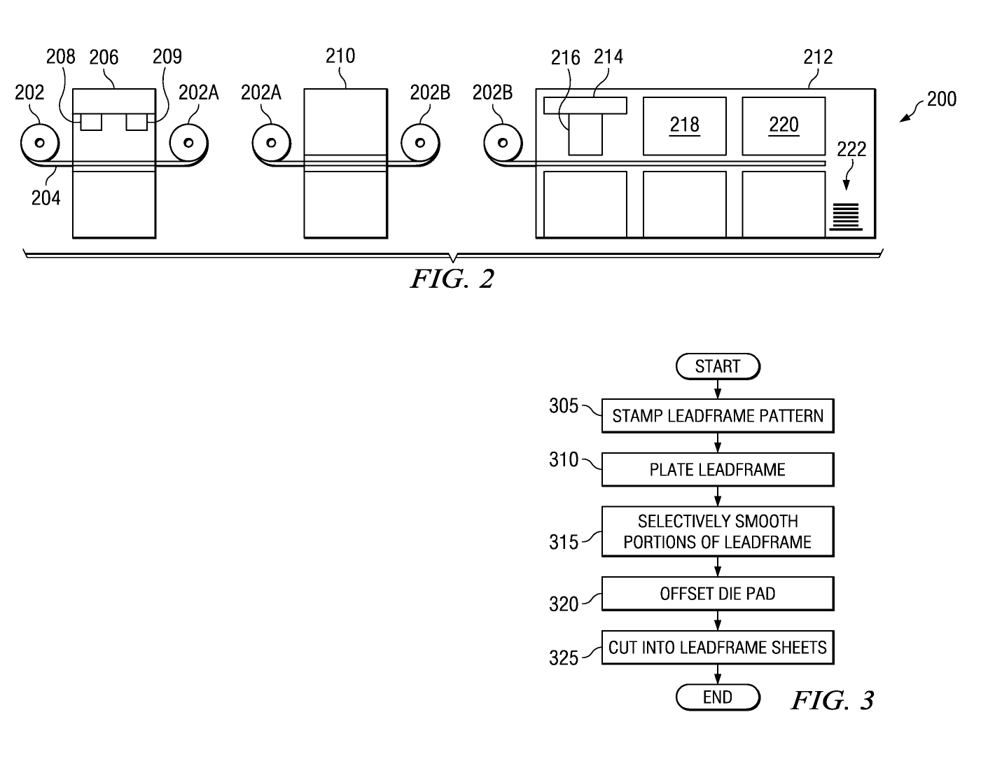

FIG. 2 illustrates an example leadframe manufacturing line 200 that may be used to form the example leadframe 100 of FIG. 1. The example leadframe manufacturing line 200 of FIG. 2 forms leadframe sheets 222 from a coil 202 of conductive material (e.g., a copper, a copper alloy, etc.) that is unrolled to form a conductive sheet 204. The example tools 206, 210, 212 of FIG. 2 perform one or more operations or processes on respective portions of the conductive sheet 204. The example tools 206, 210 and 212 of FIG. 2 are generally located in different portions of a manufacturing facility. For example, a plating tool 210 may be located in a chemically resistant environment, and a cut and offset tool 212 may be located in a quasi-clean room to reduce the introduction of impurities. In such examples, coils of material 202A and 202B are moved from tool to tool within the manufacturing facility.

To pattern leadframes 100, the example leadframe press 200 of FIG. 2 includes any type of stamping or blanking press 206. The example stamping press 206 or FIG. 2 includes any number of die (two of which are designated at reference numerals 208 and 209) that selectively stamp out, form, pattern, coin or any combination thereof the conductive sheet 204 to form the portions of a leadframe 100 (e.g., the example external leads 108, the example internal leads 112, the example die pad 114, etc. of FIG. 1). In other examples, portions of the conductive sheet 204 can be removed by any number or type(s) of other processes, such as, for example, an etching process, laser cutting, etc. The leadframes 100 formed by the stamping press 206 are coiled into a second coil 202A.

To plate the conductive sheet 204 after pattern forming, the example leadframe press 200 of FIG. 2 includes any type of plating tool 210. While the example plating tool 210 of FIG. 2 is shown as a single tool, a plating tool may include any number or types of chemical stations or baths to prepare, treat or plate the leadframes 202A. The example plating tool 210 of FIG. 2 plates the patterned leadframes 202A with one or more layers of one or more metals to, for example, facilitate bonding of bonding wires to the leadframes 100. In some examples, a first nickel (Ni) layer and a second nickel layer are deposited. The first nickel layer is a rough layer, and the second nickel layer is a smoothing layer applied to adjust or control the roughness of the resulting granular surface 122. The example plating tool 210 also deposits a palladium (Pd) layer on top of the nickel layers to prevent the nickel from oxidizing, and a gold (Au) layer to improve wetting time. Specifically, the palladium layer and gold layer are deposited over the rough nickel layer, thereby forming the granular surface 122 of the leadframe 100. In some examples, an etching process may be used to cause a plated or base metal layer to form the granular surface 122. As described above, the granular surface 122 improves the adhesion between the leadframe 100 and a molding compound. The plated leadframes 100 are coiled onto a coil 202B.

To offset portions of the plated leadframes 202B, the example lead press 200 of FIG. 2 includes a cut and offset tool 212. To selectively smooth portions of the granular surface 122 of the leadframes 100, the example cut and offset tool 212 of FIG. 2 includes a planishing station 214. The example planishing station 214 of FIG. 2 includes a planishing punch 216 to compress selected portions of the leadframes 202B. The example punch 216 of FIG. 2 contacts one or more portions of the granular surface 122, thereby compressing the granular surface 122 to form the non-granular portions 124 and 126. In some examples, the planishing punch 216 contacts a leadframe 100 multiple times to form the smoothed portions 124 and 126. Additionally or alternatively, the planishing punch 216 may be constructed to simultaneously strike multiple portions of one or more leadframes 100. The example punch 216 of FIG. 2 is configured to contact approximately 80% of the desired non-granular portions 124 and 126. In some examples, the punch 218 reduces the thickness of the non-granular portions 124 and 126 of the leadframe 100 by less than 5%.

The example cut and offset tool 212 of FIG. 2 also includes an offset station 218 that, among other things, offsets the die pads 114 of the leadframes 100 such that an integrated circuit attached to a die pad 114 is coplanar with the internal leads 112.

To cut the conductive sheet into the leadframe sheets 222, the example cut and offset tool 212 of FIG. 2 includes a cutting station 220. The example cutting station 220 of FIG. 2 cuts the planished and offset leadframes 202B into portions (e.g., squares, rectangles, strips, etc.) having one or more leadframes 100 thereon (block 210).

While an example leadframe manufacturing line 200 has been illustrated in FIG. 2, one or more of the elements, tools or devices illustrated in FIG. 2 may be combined, divided, re-arranged, omitted, eliminated or implemented in any other way. For example, while, for the sake of clarity, the example leadframe manufacturing line 200 of FIG. 2 is illustrated as a single manufacturing system, a leadframe manufacturing line may include one or more tools or stations that are located in the same or different geographical locations. Moreover, a leadframe manufacturing line may include one or more elements, tools, stations or devices in addition to, or instead of, those illustrated in FIG. 2, or may include more than one of any or all of the illustrated elements, tools and devices.

FIG. 3 is a flow chart of an example process that may be carried out to form the example leadframe 100 of FIG. 1. The example process of FIG. 3 may be carried out by one or more pieces of manufacturing equipment (e.g., the example leadframe press 200 of FIG. 2), one or more processors, one or more controllers or any other suitable processing devices. For example, the example process of FIG. 3 may be embodied in coded instructions stored on a tangible medium such as a flash memory, a read-only memory (ROM), a random-access memory (RAM), or any combination thereof associated with a processor. Alternatively, some or all of the example process of FIG. 3 may be implemented using any combination(s) of hardware or firmware or software. Also, some or all of the example process of FIG. 3 may be implemented manually or as any combination of any of the foregoing techniques, for example, any combination of firmware, or software, or discrete logic or hardware. Further, many other methods of implementing the example process of FIG. 3 may be employed. For example, the order of execution of the blocks may be changed, or one or more of the blocks described may be changed, eliminated, sub-divided, or combined.

The example process of FIG. 3 begins with the example stamping tool 206 of FIG. 2 stamping, blanking or otherwise processing a portion of a base material such as, for example, a portion of the example conductive sheet 204 to form one or more leadframe patterns (i.e., the die pads 114, the internal leads 112, etc.) (block 305). The example plating tool 210 plates the thus formed leadframe(s) with one or more layers of metal to form the example granular surface 122 of FIG. 1 (block 310).

The example planishing tool 216 selectively compresses portions of the granular surface 122 to form the less granular surfaces 124 and 126 (block 315). The example offset tool 214 of FIG. 2 offsets the die pad 114 of each plated leadframes (block 320). The example cutting tool 220 then cuts the selectively planished and offset sheet 202B into sheets containing one or more leadframes 100 thereon (block 325).

Although certain methods, systems, and articles of manufacture have been described herein, the scope of coverage of this patent is not limited thereto. To the contrary, this patent covers all methods, systems, and articles of manufacture fairly falling within the scope of the appended claims either literally or under the doctrine of equivalents.

What is claimed is:

1. A packaged integrated circuit chip comprising:
a bond wire;
a leadframe having a die pad coupled to a carrier rail, and an inner lead coupled to an outer lead via a dam bar, the inner lead having a first portion having a rough surface and a second portion having a smoothed surface, a first end of the bond wire attached to the second portion of the inner lead;
an integrated circuit attached to the die pad, a second end of the bond wire attached to a pad disposed on the integrated circuit; and
a molding compound to encapsulate the inner lead, the integrated circuit and the bond wire.

2. The packaged integrated circuit chip as defined in claim 1, wherein the die pad has a third portion having a rough surface and a fourth portion having a smoothed surface.

3. The packaged integrated circuit chip as defined in claim 1, wherein the rough surface enhances an adhesion of the molding compound to the inner lead, and the smoothed surface extends a working life of a wire bonding tool used to attach the bond wire to the lead.

4. A leadframe for a semiconductor package, the leadframe comprising:
a die pad to receive an integrated circuit and coupled to a carrier rail; and
an inner lead to receive a bond wire and coupled to an outer lead via a dam bar, the inner lead having a first portion having a rough surface and a second portion having a reduced roughness surface relative to the first portion.

5. The leadframe as defined in claim 4, wherein the die pad has a third portion having a rough surface and a fourth portion having a reduced roughness surface.

6. The leadframe as defined in claim 4, wherein the second portion of the inner lead is located at a first end of the inner lead adjacent the die pad.

7. The leadframe as defined in claim 4, wherein the rough surface enhances mold-to-leadframe adhesion, and the reduced roughness surface extends a working life of a wire bonding tool.

8. A method comprising:
processing a first conductive material to form a leadframe, the leadframe having a die pad and a lead;
forming a layer of a second conductive material on the leadframe, the layer having a granular surface; and
selectively planishing the layer to smooth a surface of the leadframe to have a selectively less granular surface.

9. The method as defined in claim 8, wherein the smoothed surface has a reduced roughness compared to the granular surface.

10. The method as defined in claim 8, wherein planishing the surface of the leadframe comprises selectively compressing an end of the lead adjacent the die pad.

11. The method as defined in claim 8, wherein planishing the surface of the leadframe comprises selectively compressing a portion of the die pad.

12. The method as defined in claim 11, wherein planishing the surface of the leadframe comprises striking the layer with a planishing punch.

13. The method as defined in claim 12, wherein the planishing punch strikes approximately 80 percent of a distal end of a lead.

14. An apparatus comprising:
a stamping tool to form a leadframe in a first conductive material, the leadframe having a die pad and a lead;
a plating tool to form a layer of a second conductive material on the leadframe, the layer having a granular surface; and
a cut and offset tool to selectively planish the layer to smooth a surface of the leadframe.

15. The apparatus of 14, wherein the cut and offset tool comprises:
a planishing punch to selectively planish the layer; and
an offset station to offset the die pad relative to the lead; and
a cutting station to cut the first conductive material to form a sheet that includes the leadframe.

16. The apparatus of 15, wherein the planishing punch strikes an end of the lead adjacent the die pad.

17. The apparatus of 15, wherein the planishing punch strikes a portion of the die pad.
